(19) United States
(12) Patent Application Publication
(10) Pub. No.: US 2026/0302692 A1
(43) Pub. Date: Oct. 1, 2026

(54) BOARD-TO-BOARD MECHANICAL CONNECTION CONFIGURATION

(71) Applicant: Aivres Systems Inc., San Jose, CA (US)

(72) Inventor: Tsung Ho CHEN, New Taipei City (TW)

(21) Appl. No.: 19/092,706

(22) Filed: Mar. 27, 2025

(51) Int. Cl. H01R 13/629; H01R 12/71; H01R 13/635; H01R 43/26

(52) U.S. Cl. CPC H01R 13/62944; H01R 12/716; H01R 13/635; H01R 43/26

(57) ABSTRACT

A board-to-board assembly for inclusion in a computer system includes a first board fixture in a fixed relation to a first printed circuit board and a second board fixture in a fixed relation to a second printed circuit board. The first and second printed circuit boards are parallel and separated in a stacking direction. The first and second board fixtures are operatively associated with one or more rack-and-pinion mechanisms configured to translate the first and second printed circuit boards with respect to the stacking direction, for example, to mate a plurality of board-to-board electrical connectors.

### TECHNICAL FIELD

This patent application relates to components for computing systems, in particular, to a configuration for mechanically connecting printed circuit boards in a parallel or mezzanine orientation.

### BACKGROUND

Computer systems are assembled from various electronic components and devices that are communicatively interconnected and physically arranged and accommodated in a common chassis or enclosure. For example, specific components such as integrated circuits may be mounted to one or more rigid printed boards (PCBs) configured for the routing of electronic data signals and electrical power that may be accommodated within the enclosure. The printed circuit board may include a rigid planar substrate made of an insulative material such as phenolic resin having electrically conductive traces disposed on the planar surfaces or embedded in the laminated structure of the board. Electronic devices mounted to the planar surface of the printed circuit board are communicatively connected by the conductive traces. The arrangement and cooperative operation of the electronic components are responsible for the computational and processing functionality of the computer system.

Typically, multiple printed circuit boards having different electronic components arranged for different purposes may be installed in the same chassis and must communicate electronically with one another. Although communication can be established by wires and cables, sometimes it is desirable to physically connect two printed circuit boards directly together, eliminating wires and improving electronic communication. Direct physical connection between printed circuit boards communicatively links the local communication busses thereon improving the transfer of data signals and electrical power. Various orientations and arrangements are available for directly connecting two or more printed circuit boards together. For example, two printed circuit boards can be oriented orthogonally at right angles and thus perpendicularly intersect each other. Right angled connectors or edge connectors can be used to communicatively interface the orthogonal boards. In another example, two printed circuit boards can be placed in a parallel, spaced apart orientation. Such a board-to-board arrangement may be referred to a parallel stacked or mezzanine arrangement

### SUMMARY OF THE DISCLOSURE

To connect first and second boards together in a parallel or mezzanine arrangement, a board-to-board assembly is disclosed that includes a first board fixture and a second board fixture that cooperatively interact to situate and secure the first and second boards in a parallel and spaced apart relation with respect to a stacking direction. The first board can be fixedly situated with respect to the first board fixture and the second board can be fixedly situated with respect to the second board fixture. To translate the first and second boards with respect to the stacking direction, the first and second board fixtures are operatively associated with one or more rack-and-pinion mechanisms actuatable with respect to the stacking direction.

In a further aspect, the first rack-and-pinon mechanism and the second rack-and-pinon mechanism are spaced apart in a lateral direction, perpendicular to the stacking direction, toward laterally opposite sides of the board-to-board assembly.

In a further aspect, the first rack-and-pinon mechanism and the second rack-and-pinon mechanism are spaced apart in a traverse direction, perpendicular to the stacking direction, toward traversely opposite sides of the board-to-board assembly.

In a further aspect, the first rack-and-pinion mechanism and second rack-and-pinion mechanism each comprise a pinion gear rotationally that is attached to the first board fixture and a rack gear fixedly attached to the second board gear.

In a further aspect, the pinion gear comprises a pinion periphery that is circular with a plurality of pinion gear teeth and an actuating lever extending tangentially from the pinion periphery.

In a further aspect, the pinion gear rotates with respect to a pinion axis that is perpendicular to the stacking direction.

In a further aspect, the pinion gear comprises a ball plunger that is spring-loaded and adapted to releasably engage a detent disposed on the first board fixture.

In a further aspect, the pinion gear comprise a restraining slot disposed as an arc and radially parallel to the pinion periphery, the restraining slot receiving a restraining pin extending from the first fixture.

In a further aspect, the rack gear comprises a linear bar having a plurality of rack gear teeth disposed along the bar.

In further aspect, the first board fixture comprises a first fixture bracket and a second fixture bracket separated in a lateral direction, perpendicular to the stacking direction, and located toward laterally opposite side of the first board.

In a further aspect, the first fixture bracket and the second fixture bracket define a lateral bracket gap sized to accommodate a lateral dimension of the first board.

In a further aspect, the second board fixture is configured as a fixture channel having a channel web parallel with the planar orientation and interconnecting a first channel flange and a second channel flange extending perpendicularly from the channel web and aligned with the stacking direction.

In a further aspect, the board-to-board assembly further comprises a plurality of board-to-board electrical connectors jointly mounted between the first and second boards.

In a further aspect, the channel web comprises a plurality of connector apertures to enable mating connection of the plurality of board-to-board electrical connectors.

In another aspect, the disclosure describes a method of assembling a board-to-board assembly in a parallel or stacked arrangement includes situating a first board with respect to a first board fixture and situating a second board with respect to a second board fixture. The first and second board fixtures are associated with one or more rack-and-pinion mechanisms. The first board fixture and the second board fixture are positioned parallel to each other and separated in a stacking direction. The one or more rack-and-pinion mechanisms can be engaged to translate the first and second boards toward each other in the stacking direction.

In a further aspect, the pinion gear comprises an actuating lever extending tangentially from a pinion periphery thereof, and the step of rotating the pinion gear comprises pivoting the actuating lever to generate a mechanical advantage.

In a further aspect, the method involves locking the first and second board fixtures in a stacked relation by engaging a spring-loaded ball plunger mounted to the pinion gear with a locking detent disposed on the first fixture.

In a further aspect, the step of rotating the pinion gear comprises moving a restraining pin extending from the first board fixture within a restraining slot disposed as an arc in the pinion gear.

In a further aspect, the first board fixture comprises a second pinion gear and the second board fixture comprises a second rack gear, and the method further comprises the step of concurrently rotating the second pinion gear to mesh with the second rack gear.

In another aspect, the disclosure describes a board-to-board assembly comprising a first board having a planar configuration and a first board fixture in a fixed relation to the first board. The first board fixture comprising a pinion gear rotatably attached thereon. The board-to-board assembly also includes a second board having a planar configuration parallel to the first board and spaced apart therefrom with respect to a stacking direction orthogonal to first and second boards and a second board fixture in a fixed relation to the second board. The second board fixture includes a rack gear fixedly attached thereto and aligned in the stacking direction, the rack gear adapted to mesh with the pinion gear to move the first and second boards with respect to the stacking direction.

A possible advantage of the disclosure is that the one or more rack-and-pinion mechanisms can be located on the board-to-board assembly in a spaced apart relation to apply and distributed the actuating forces evenly, causing the first and second board fixtures to translate with respect to each other in the stacking direction. Translation of the first and second boards in the stacking direction results in simultaneous mating of a plurality of board-to-board electrical connectors associated therewith, avoiding misalignment or faulty connections. Another possible advantage is that the pinion gear of the rack-and-pinion mechanism can include an actuating lever that generates a mechanical advantage to assist in mating the board-to-board electrical connectors.

### BRIEF DESCRIPTION OF THE DRAWINGS

FIG. 1 is a perspective view of a computer system having an enclosure or chassis accommodating computer components including printed circuit boards, processing units, drives and fan modules operatively interconnected and functionally interacting with each other.

FIG. 2 is perspective assembly view of a board-to-board assembly comprised of two printed circuit boards associated respectively with first and second board fixtures and arranged in a parallel, stacked orientation and opposed with respect to each other in a stacking direction.

FIG. 3 is a perspective exploded view of the board-to-board assembly showing the first and second board fixtures separated with respect to the stacking direction.

FIG. 4 is an exploded perspective view of the first board fixture including first and second fixture brackets in between which the first printed circuit board is situated.

FIG. 5 is an exploded perspective view from the top showing the second board fixture embodied as a fixture channel configured to receive the second printed circuit board.

FIG. 6 is an exploded perspective view from the bottom showing the second board fixture including a plurality of connector apertures disposed in the fixture channel to enable mating connection of a plurality of board-to-board electrical connectors.

FIG. 7 is an exploded view of the pinion gear rotationally attached to the first and/or second fixture brackets of the first board fixture.

FIG. 8 is a perspective view of the rack-and-pinion mechanism with the pinion gear and rack gear aligned for engagement in the stacking direction.

FIG. 9 is a perspective view of the rack-and-pinion mechanism with the pinion gear and rack gear meshed together moving the first and second board fixtures coextensively together in the stacking direction.

FIG. 10 is a schematic diagram of a spring-loaded ball plunger that can be used to lock and release the rack-and-pinion mechanism.

### DETAILED DESCRIPTION

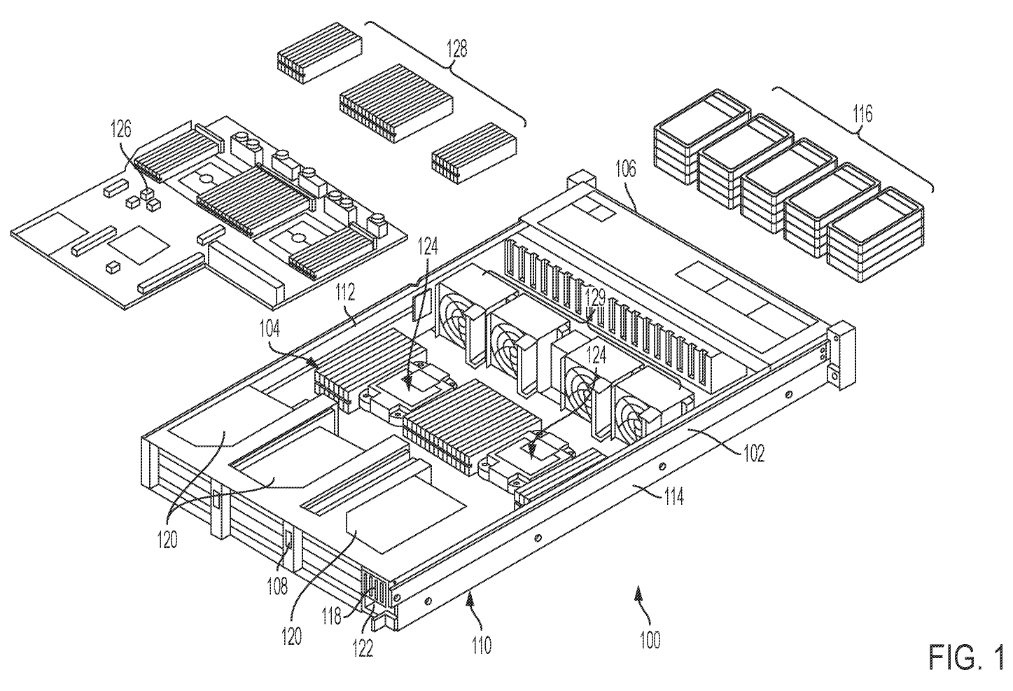

Now referring to the drawings, where whenever possible like reference numbers will refer to like elements, there is illustrated in FIG. 1 a computer system 100 comprised of various electronic devices and hardware that are cooperatively interconnected and assembled together and that may be accommodated in a common chassis 102 with the chassis cover removed. The chassis 102 can be a box-like structure made of formed sheet metal or molded plastic and that defines an internal space or chassis volume 104 for the internal computer components and electronic hardware of the computer system 100. The computer system 100 can be configured for communicative integration with a larger network or system and the chassis 102 may be designed for mounting into a rack with similar computer systems, although in other instances the computer system 100 may be a standalone configuration.

The chassis 102 can accommodate components and hardware devices like central processing units, memory modules, hard drives, power convertors, and fan units for circulating air internally about the chassis volume 104 for cooling of the internal components. The box-like chassis 102 may be rectangular in shape and can extend between a front panel 106 and rear panel 108 that are parallel to each other and located opposite one another. To complete the box-like structure, the chassis 102 can also include a bottom panel 110 that forms the planar floor of the computer system 100 and first and second upright sidewalls 112, 114 extending perpendicularly from the bottom panel 110. A removable cover may also be included to enclose the chassis volume 104. The chassis panels can be made of formed sheet metal or molded plastic structurally connected together to provide the rigid chassis 102 for support of the internal hardware components.

The front and rear panels 106, 108 can include various LED indicator lights, activation and setting buttons and switches, ports and sockets for data and power communications, and other features for interfacing with operators and other systems. For example, if the computer system 100 is a data server, the front panel 106 can be designed as a structural frame to accommodate one or more storage drives 116, which may be hard disk drives or solid state drives providing non-volatile data storage and memory. The individual storage drives 116 can be aligned adjacently in a side-by-side arrangement or can be sorted into vertical stacks. The number and types of storage drives can be selected and adjusted for scalability to expand the functionality of the computer system.

The rear panel 108 can be configured to accommodate one or more power supply units 118 to receive electrical power for operation of the computer system 100. The power supply units 118 may include sockets designed to mate with an external power plug and may be designed as a rectifier or convertor to adjust the electrical characteristics such as voltage and phase of the supplied power. To expand the functionality of the computer system 100, the rear panel 108 can also be configured to accommodate one or more installable PCI expansion cards 120. PCI expansion cards 120 are typically configured as printed circuit boards with circuitry mounted thereon for expanded functionality such as, for example, graphics processing or communicative networking. To further establish network connectivity with external systems, the rear panel 108 can also accommodate one or more I/O ports 122 for the exchange of electronic data signals.

To execute software encoded instructions included in the executable applications and programs during operation, the computer system 100 can include one or more processors 124 or central processing units. The processors 124 can include electronic circuitry configured to conduct logical operations and may be implemented as an integrated circuit or chip. In an example, the computer system 100 can be designed for parallel operation and may include two or more processors 124 to increase performance speeds and capacity. The processors 124 can be mounted to a common printed circuit board referred to as the motherboard 126 (also shown removed from chassis 102) designed to enable communication and interfacing with the processors through electronic data and power signals. The motherboard 126 can also accommodate other core computing subsystems such as main memory 128, which may be embodied as a plurality of volatile random access memory modules in a DIMM format. The motherboard 126 can be centrally located in the chassis 102 and may be fixed to and supported on the bottom panel 110, although other positions and orientations are possible.

To maintain the temperature in the chassis 102 within operating ranges and avoid possible damage to the electronic devices therein, the computer system 100 may be operatively associated with a thermal management system. For example, one or more fan units 129 can be included in the chassis 102 and are adapted to circulate airflow within the internal volume 104. In another example, the computer system 100 can be designed with a liquid cooled functionality.

It is typically necessary to communicatively interconnect the motherboard 126 with other system components and, as indicated, it is often desirable to directly connect the motherboard 126 with other printed circuit boards that are sometime referred to as daughterboards. The direct physical and mechanical connection of two printed circuit boards may be referred to as a board-to-board assembly.

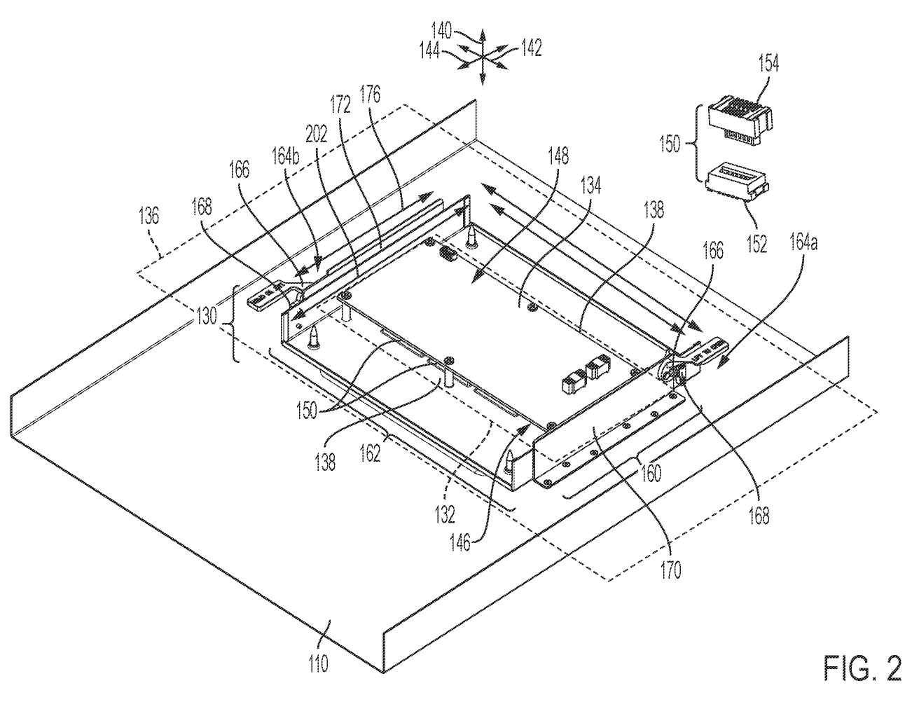

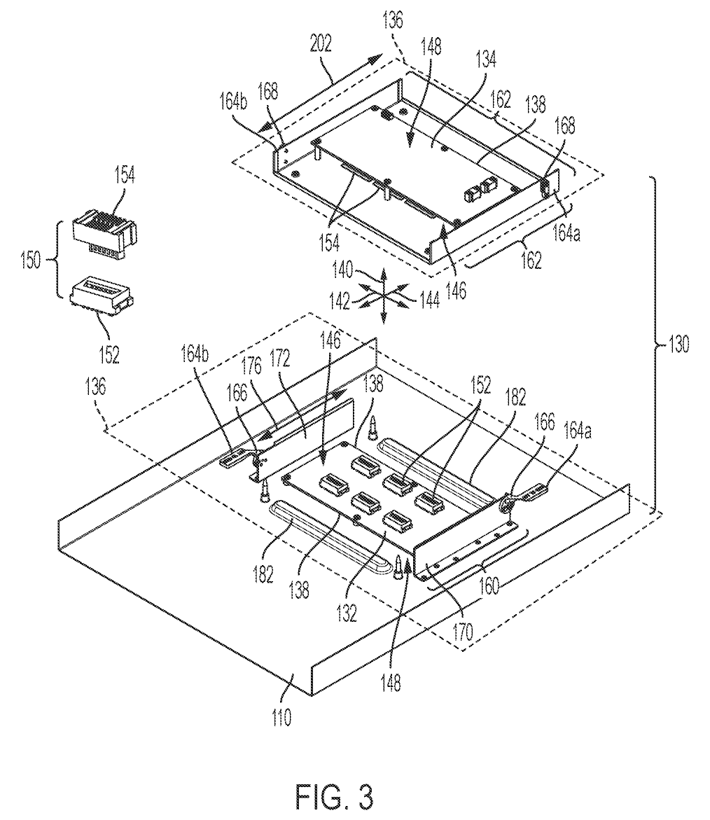

Referring to FIGS. 2 and 3, there is shown a board-to-board assembly 130 in accordance with the disclosure wherein a first printed circuit board, referred to hereafter as board 132, which may be designated as the motherboard (indicated in dashed lines in FIG. 2), is oriented in a parallel, spaced relation with a second printed circuit board, referred to hereafter as board 134, that may be designated as the daughterboard. The parallel, spaced apart orientation of the first and second boards 132, 134 in the board-to-board assembly 130 may be referred to a mezzanine arrangement or stacked arrangement. The mezzanine or stacked orientations of the board-to-board assembly 130 distinguishes other common board-to-board arrangements such as orthogonal in which two boards perpendicularly contact or intersect each other and a horizontal arrangement wherein two boards are arranged in a coplanar, side-by-side or butt ended configuration.

The printed circuit boards for the first and second boards 132, 134 are typically constructed from a rigid, electrically non-conductive substrate made of an insulative material such as phenolic resin. A pattern of conductive traces can be disposed over the surface of the substrate. Electronic devices can be mounted to the surface of the substrate to make electrical contact with the conductive traces thereby establishing electronic communication between the mounted devices. Any suitable surface mounting technique can be used to mount the electronic devices and/or connectors to the surfaces of the first and second boards. In various examples, the printed circuit boards comprising the first and second boards 132, 134 can be made of several suitable insulative substrates and patterned conductive traces laminated or adhered together to increase the capacity and thickness of the first and second boards 132, 134

The first and second board 132, 134 can be characterized by a rigid, planar configuration and each may define a planar orientation 136 (indicated in dashed lines). When the first and second boards 132, 134 are situated in the board-to-board orientation, their planar orientations 136 are parallel and opposed to each other. In addition, geometric shape of the first and second boards 132, 134 in the planar orientation may be a rectangular parallelogram and each board may have a plurality of linear, intersecting board edges that define a board periphery 138 on each of the first and second boards.

The spaced-apart relation of the parallel first and second boards 132, 134 in the mezzanine or stacked arrangement of the board-to-board assembly 130 results in separating the boards with respect to an assembly or stacking direction 140 in the z-axis as indicated. For reference, the stacking direction 140 can be relationally associated with other coordinate directions including a lateral direction 142 and a traverse direction 144 that may be both perpendicular to the stacking direction and parallel with the planar orientations of the first and second boards 132, 134.

The parallel, spaced apart relation of the first and second boards 132, 134 with respect to the stacking direction 140 results in the flat, planar configuration of each board being associated with opposing faces 146 directed toward each other and with external faces 148 directed outwardly and away from each other with respect to the stacking direction 140. The opposing faces 146 and the external faces 148 are the opposite exterior surfaces of each of the planar first and second boards 132, 134. To electrically interconnect the first and second boards 132, 134 together and transfer electrical power and/or data signals therebetween, a plurality of board-to-board electrical connectors 150 (shown in detail) can be mounted on the opposing faces 146.

The board-to-board electrical connectors 150 can be assembled of hardware components that are distributed between and surface mounted on the opposing faces 148 of the first and second boards 132, 134. The board-to-board electrical connectors 150 are designed to mate together and establish an electrical connection when the first and second boards 132, 134 are moved together in the stacking direction 140. For example, a suitable electrical connector 150 may be designed as a header configuration including a female socket 152 mounted, for example, to the first board 132 and a male header 154 mounted to the second board 134. The female socket 152 can define a slot or gap into which a protruding tongue or prongs on the male header 154 can be inserted and received. The female socket 152 can include a plurality of electrically conductive contact terminals located within the slot and the male header 154 can include a corresponding arrangement of conductive terminals or pins that make sliding contact when the board-to-board electrical connectors 150 are mated.

The complementary components of the plurality of board-to-board electrical connectors 150 may be spatially arranged on each of the first and second boards 132, 134 in a predetermined alignment pattern. For example, to mate the board-to-board electrical connectors 150, the female sockets 152 and the male headers 154 must be aligned together with respect to the stacking direction 140. That requires orientating the first and second boards 132, 134 in an overlapping alignment with respect to the lateral and traverse directions 142, 144. Moreover, the board-to-board electrical connectors 150 can be characterized by an insertion force, aligned along the stacking direction 140, that must be produced to insert the male header 154 into the female socket 152. The insertion force is also required to separate the board-to-board electrical connectors 150 when disassembling the board-to-board assembly.

To facilitate alignment of the first and second boards 132, 134 and to direct the insertion force towards the board-to-board electrical connectors 150, the board-to-board assembly 130 can include a first board fixture 160 and a second board fixture 162 that are configured to cooperatively interact with each other. The first board fixture 160 can be operatively associated with the first board 132 and the second board fixture 162 can be operatively associated with the second board 134. The first and second board fixtures 160, 162 function to situate and hold the first and second boards 132, 134 in the correct parallel orientations and planar alignment relative to each other during stacking.

Moreover, to move the first and second boards 132, 134 toward each other in the stacking direction 140, the first and second board fixtures 160, 162 can be associated with a board-to-board mechanical connector comprised of one or more pairs of intermeshing gears configured as a rack-and-pinion mechanism 164a, 164b. The rack-and-pinion mechanisms 164a-b function to forcibly drive the first and second boards 132, 134 with respect to the stacking direction 140 to assist in mating and/or releasing the plurality of board-to-board electrical connectors 150. In a preferred arrangement, the board-to-board mechanical connectors may include a pair of rack-and-pinion mechanisms 164a-b that are laterally and traversely spaced apart with respect to the planar orientation 136 of the board-to-board assembly 130.

In an example, the rack-and-pinion mechanisms 164a-b can each include a pinion gear 166 that is operatively associated with the first board fixture 160 and a rack gear 168 that is operatively associated with the second board fixture 162. However, the operatively associations of the rack-and-pinion mechanism 164a-b can be reversed and/or altered provided the first and second board fixtures 160, 162 assists in situating and aligning the pinion gear 166 and rack gear 168 for engagement.

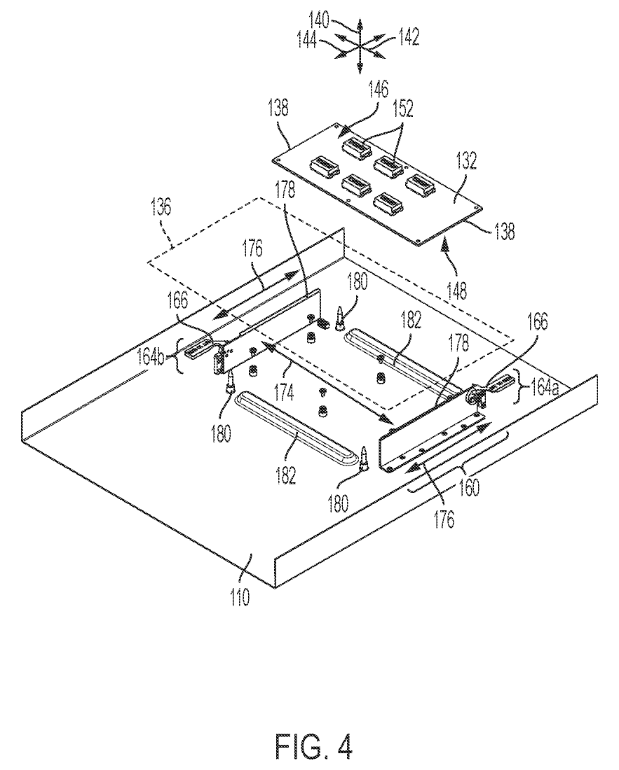

To form the first and/or second board fixtures 160, 162, the fixture parts may be associated and other structures included in the chassis 102. For example, referring to FIG. 4, the first board 132 of the board-to-board assembly 130, which may be the motherboard, can be mounted on the bottom panel 110 of the chassis 102. To fixedly situate the first board 132 within the chassis volume 104, a plurality of first standoffs or spacers can be used to separate the external faces 148 from the interior surface of the bottom panel 110 and thereby elevate the first board 132 in the stacking direction.

To connectively interact with the second board 134 spaced apart in the stacking direction 140, the first fixture 160 can include a pair of fixture brackets, designated as a first fixture bracket 170 and a second fixture bracket 172, that are mounted to and extend upright in the stacking direction 140 from the planar surface of the bottom panel 110. The first and second fixture brackets 170, 172 can be spaced apart and separated in the lateral direction 142 so as to be located at either lateral side or end of the first board 132. The first and second fixture brackets 170, 172 thus define a lateral bracket gap 174 in the lateral direction 142 that is sized to accommodate the lateral dimension or width of the first board 132.

The first and second fixture brackets 170, 172 can be elongated, linear structures that are aligned and extend in the traverse direction 144 perpendicular to the lateral direction 142. The first and second fixture brackets 170, 172 can thus also define a traverse bracket length 176 in the traverse direction 144 that may exceed the traverse dimension of the first board 132 so that the traverse edges of the fixture brackets extend and are located beyond the traverse edge of the board periphery 138. The first and second fixture brackets 170, 172 can be constructed as structural angles having perpendicularly intersecting legs, one of which is adjacent to the bottom panel 110 and the other of which extends perpendicularly upright in the stacking direction 140.

To assist in guiding the second board fixture 162 in between the first and second fixture brackets 170, 172 of the first board fixture 160 when the first and second boards 132, 134 are moved toward each other in the stacking direction 140, the fixture brackets can include flared upper edges 178 that diverge laterally outward from each other in the lateral direction 142. The flared upper edges 178 can be formed by bending or forming the upright leg of the fixture brackets 170, 172 laterally outwardly. To form the angled shape and flared upper edges 178, the first and second fixture brackets 170, 172 can be made of a metallic material, or alternatively may be molded thermoplastic.

To further assist in situating and fixating the board-to-board assembly 130 within the chassis 102, the first board fixture 160 can be associated with other structural components. For example, to further assist in guiding the second board fixture 172 with respect to the first board fixture during stacking, a plurality of guide pins 180 can be mounted on and project orthogonally upwardly from the surface of the bottom panel 110 in the stacking direction 140. The plurality of guide pins 180 can be shaped as cylindrical prongs and can be located outwardly about the board periphery 138 of the first board 132. In the example where the first board 132 is rectangular, the plurality of guide pins 180 can be arranged in a quadrilateral pattern to be located outwardly about the first board 132, although other patterned arrangements may be used.

To abut against and prevent the second board fixture 162 from bottoming out against the first board 132, one or more abutment bosses 182 can be formed into the bottom panel 110 of the chassis 102. The abutment bosses 182 project upwardly in the stacking direction 140 and may extend above the opposing face 148 of first board 132 so that the second board fixture 162 makes abutting contact therewith when assembled in the stacked board-to-board assembly 130.

The abutment bosses 182 can be formed as raised reliefs pressed into the bottom panel 110 extending in the stacking direction 140 and may be aligned in the lateral direction 142. The abutment bosses 182 may be spaced apart in the traverse direction 144 and can be located on either traverse edge of the board periphery 138 of the first board 132. The abutment bosses 182 can be located beyond the traverse bracket length 176 associated with the first and second fixture brackets 170, 172 in the traverse direction for exposure to abut against the second board fixture 162.

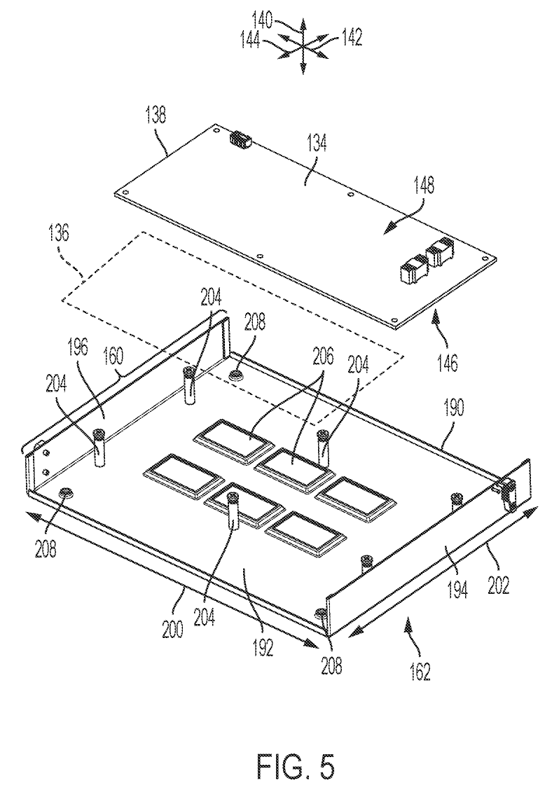

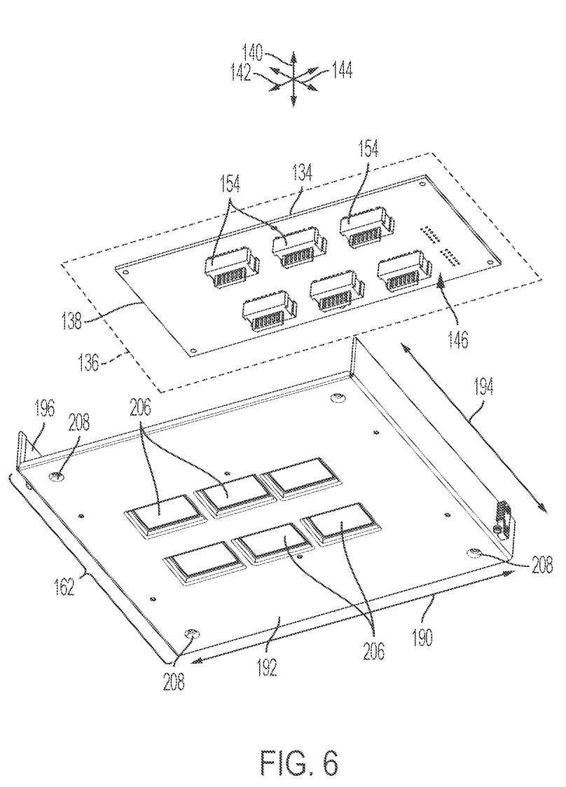

Referring to FIGS. 5 and 6, the second board fixture 162 can be geometrically and structurally configured to interact with the laterally spaced apart first and second fixture brackets 170, 172 of the first board fixture 160 and the abutment bosses 182 of the bottom panel 100. For example, the second board fixture 162 can include a fixture channel 190 that may be a three-sided C-shaped channel having a channel web 192 that extends between opposing, parallel channel flanges 194, 196 that are perpendicularly joined to the channel web 192. The fixture channel 190 can be constructed from formed and pressed sheet metal.

When the second board fixture 162 is oriented for stacking with the first board fixture 160, the channel web 192 can be orthogonal to the stacking direction 140 and the first and second channel flanges 194, 196 are aligned with the stacking direction 140. The channel web 192 may have a lateral channel width 200 in the lateral direction 142 measured between the spaced-apart first and second channel flanges 194, 196 and may have a traverse channel length 202 in the traverse direction 144. The first and second channel flanges 194, 196 can extend coextensive with the traverse channel length 202.

The second board 134, which may be a daughterboard, can be attached to the fixture channel 190 with the planar orientation 136 parallel to and spaced apart from the channel web 192. To space apart the second board 134 and fixture channel 190, a plurality of standoffs 204 or spacers can be located between opposed faces 146 and the channel web 192 separating them in the stacking direction 140. The standoffs 204 can be cylindrical rods configured for separating printed circuit boards and can be mounted to the second board 134 and/or fixture channel 190 by threaded connections.

To enable the board-to-board electrical connectors to interface and mate, the fixture channel 190 can include a plurality of connector apertures 206 disposed through the channel web 192. The connector apertures 206 can have any suitable shape, for example, rectangular, and can be arranged in a pattern on the channel web 192 to correspond with the alignment pattern of the partial components of the board-to-board electrical connectors 150 mounted to the opposing face 146 of the second board 134. The corresponding components of the board-to-board electrical connectors 150 are therefore aligned with and can be accessed through the connector apertures 206 for mating when the first and second boards 132, 134 are stacked in the board-to-board assembly 130. To receive and interact with the plurality of guide pins 180 on the bottom panel 110, the fixture channel 190 can include a corresponding plurality of guide apertures 208 disposed though the channel web 192 in a complementary pattern.

During assembly, the first and second board fixtures 160, 162 geometrically interact to align the first and second boards 132, 134 in stacked direction 140. For example, referring back to FIGS. 2 and 3, the lateral bracket gap 174 between the fixture brackets 170, 172 can be slightly greater in dimension than the lateral channel width 200 of the fixture channel 190 so that the second board fixture 162 is received laterally between the first and second fixture brackets 170, 172 When the first and second board fixtures 160, 162 are moved toward each other in the stacking direction 140, the fixture brackets 170, 172 and the channel flanges 194, 196 can make sliding contact with each other. Moreover, the structurally fixed relation of the components moves the mating components of the board-to-board electrical connectors 150 into alignment.

As the second board fixture 162 translates toward the first board fixture 160 in the stacking direction 140, the flare upper edges 178 may initially contact the web channel 192 and assist in directing the second board fixture 162 between the fixture brackets 170, 172. Furthermore, the guide pins 180 projecting from the bottom panel 110 can be received in the plurality of guide apertures 208 on the fixture channel 190 for further alignment. The web channel 192 of the second board fixture 162 is superposed over the bottom panel 110 associated with the first board fixture 162 and the first and second boards 132, 134 are parallel and spaced in the stacking direction 140.

To continue forcibly moving the first and second boards 132, 134 toward each other in the stacking direction 140 and thereby mate the board-to-board electrical connectors 150, the rack-and-pinion mechanisms 164a-b associated with the first and second board fixtures 170, 172 can be engaged to create leverage or a mechanical advantage. In the illustrated example, the pair of rack-and-pinion mechanisms 164a-b can each include a pinion gear 166 attached to the first board fixture 160 and a corresponding rack gear 168 can be attached to the second board fixture 162. For example, the pinion gears 166 may be structurally attached to the first and second fixture brackets 170, 172 and the rack gears 168 attached to the channel flanges 194, 196 at complementary locations so that when the first and second board fixtures 160, 162 are aligned, the pinion gears and rack gears are likewise aligned in proximity for engagement.

Actuated engagement of the pinion gear 166 and rack gear 168 forcibly moves the first and second board fixtures 160, 162 towards each other in the stacking direction 140 to overcome the insertion resistance associated with the board-to-board electrical connectors 150. To evenly distribute the actuation forces generated by engaging the pinion gear 166 and rack gear 168, at least two rack-and-pinion mechanisms 164a-b can be included on the first and second board fixtures 160, 162 and situated at laterally and traversely opposite locations with respect to the board-to-board assembly 130. For example, the first and second rack-and-pinion mechanisms 164a-b can be separated in the lateral and traverse directions 142, 144.

Accordingly, when the two rack-and-pinion mechanisms 164a-b are concurrently actuated, the actuating forces generated by engagement of the pinion gear 166 and rack gear 168 will be more evenly distributed across the planar orientation 138 associated with the first and second boards 132, 134. The first and second board fixtures 160, 162 are therefore linearly translated evenly towards one another in the stacking direction 140, thereby maintaining the parallel orientation between the first and second boards 132, 134. Linear translation of the boards 132, 134 in the stacking direction 140 results in simultaneous mating of the plurality of board-to-board electrical connectors 150 avoiding faulty misconnections or mating misalignments.

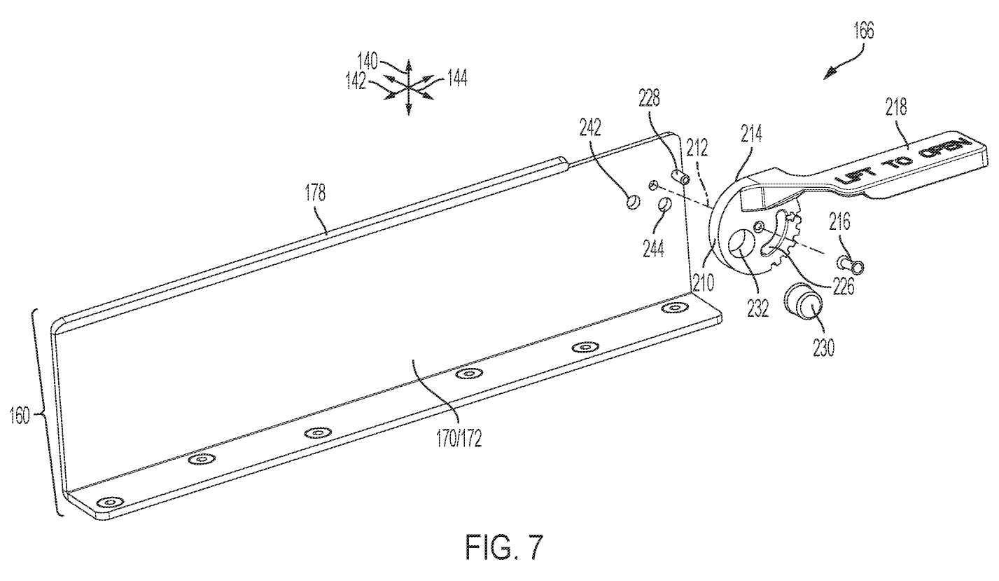

To direct an actuating force to the rack gear 168, referring to FIG. 7, the pinion gear 166 can be a circular structural disk 210 that is rotatable with respect to the first board fixture 160 under an applied force. For example, the circular pinion gear 166 can be configured to rotate about a pinion axis 212 and can have a pinion periphery 214 that is circular around the structural disk 210 with a plurality of pinion gear teeth that are partially disposed around the circular pinion periphery 214 in a radial arc. The pinion gear teeth on the pinion periphery 214 may be straight and parallel with the pinion axis 212.

The pinion gear 166 can be rotationally attached to an exterior surface of the first and/or second fixture brackets 170, 172 and located towards a traverse edge of the bracket structure in the traverse direction 144. The axial face of the circular pinion gear 166 can sit flush with the exterior surface of the first and/or second fixture brackets 170, 172 and can make sliding contact therewith during rotation.

To enable rotation, the pinion gear 166 can be attached to the first and/or second brackets 170, 172 by a pinion axle 216 that is aligned with the pinion axis 212 and inserted through a central aperture disposed in the center of the circular pinion disk 210. The pinion axle 214 can also be structurally fixed to a corresponding aperture in the first and/or second fixture brackets 170, 172 in the lateral direction 142. Accordingly, when the pinion gear 166 is inserted onto the pinion axle 216, the pinion axis 212 aligns with the lateral direction 142 and orthogonal to the stacking direction. Rotation of the pinion gear 166 moves the circular pinion periphery 214 and the gear teeth thereon with respect to the stacking direction 140 and the traverse direction 144.

To apply a force to cause rotation, the pinion gear 166 can include an actuating lever 218 that extends tangentially from an edge of the circular pinion periphery 212. The actuating lever 218 can be linear or straight in shape and can be configured or fashioned for pressing contact with hands or fingers. When a pressing force is applied to the distal end of the actuating lever 218, the pinion gear 160 rotates with respect to the pinion axis 210. The force applied to the actuating lever 218 can cause rotation of the pinion gear 166 in either the clockwise or counterclockwise directions about the pinion axis 212.

The relative length of the actuating lever 218 relative to the diameter of the circular pinion periphery 214 of the structural disk 210 can generate leverage or a mechanical advantage increasing the actuating force in the stacking direction 140. For example, application of a linear force to the distal end of the actuating lever 218 will be amplified at the circular pinion periphery 214 due to the dimensionally longer length of the actuating lever 218 relative to the dimensionally smaller diameter of the circular pinion periphery 214 as the structural disk 210 rotates with respect to the pinion axis 212. The leverage and increased acting force can assist in mating the plurality of electrical contacts by movement in the stacking direction.

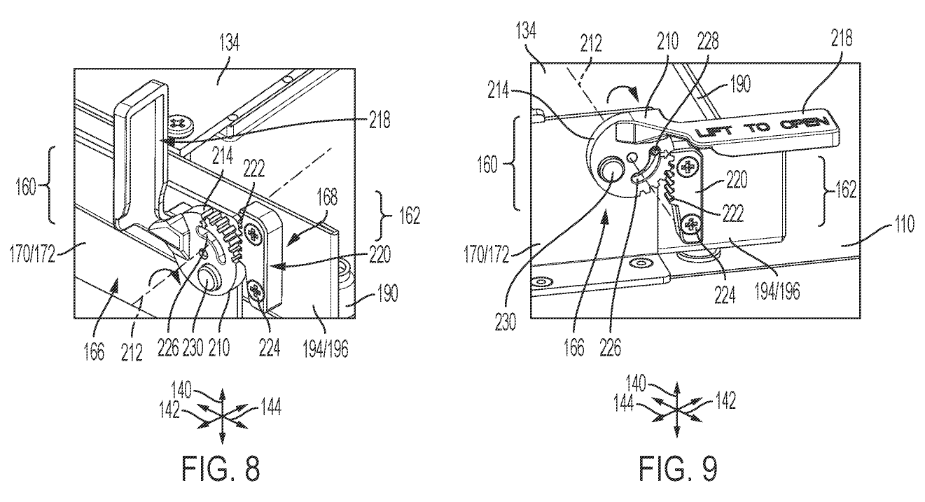

Referring to FIGS. 8 and 9, to align and transmit the actuating force associated with rotation of the pinion gear 166 attached to the first board fixture 160 to the second board fixture 162, the pinion gear meshes with the rack gear 168 attached to the fixture channel 190 of the second board fixture 160. The rack gear 168 can be configured as a linear bar 220 that is joined to the first and second channel flanges 194, 196 of the fixture channel 190 so that its linear extension aligns with the stacking direction 140. The rack gear 168 may have a plurality of linearly aligned rack gear teeth 222 that extend in the stacking direction 140 of the board-to-board assembly 130. The gear rack 220 can be fixedly attached to the first and second channel flanges 194, 196 by threaded fasteners 224.

When the second board fixture 162 is positioned between the laterally spaced apart first and second fixture brackets 170, 172 of the first board fixture 160, as shown in FIG. 8, the pinion gear teeth of the pinion gear 166 and the rack gear teeth of the rack gear 168 can be aligned to mesh. An actuating force can be applied to the distal end of the actuating lever 218 causing rotation of the pinion gear 166 with respect to the pinion axis 212. Correspondingly, the pinon gear teeth disposed circumferentially around the circular pinion periphery 214 will rotate about the pinion axis 212 and mesh with the rack gear teeth 222 disposed linearly along the linear rack bar 220.

Because the pinion gear 166 is rotationally fixed with respect to the first and/or second fixture brackets 170, 172, which may be fixedly mounted to the bottom panel 110 of the chassis, meshing of the pinion gear teeth and rack gear teeth moves the rack gear 168 and the fixture channel 190 fixed thereto linearly in the stacking direction 140. Accordingly, the fixture channel 190 of the second board fixture 162 is moved between the first and second fixture brackets 170, 172 such that the first and second board fixtures 160, 162 are coextensive with respect to each other in the stacking direction 140 as shown in FIG. 9. The first and second fixture brackets 170, 172 and the corresponding first and second channel flanges 194, 196 can make adjacent sliding contact when the first and second fixture brackets 170, 172 are translated with respect to each other in the stacking direction 140. Thus, the rack-and-pinion mechanisms 164a-b convert a rotational force applied to the pinion gear 166, causing rotation about the pinion axis 212 perpendicular to the stacking direction 140, to a linear force applied to the rack gear 168 and aligned parallel with the stacking direction.

The rack-and-pinion mechanisms 164a-b thus convert a rotational actuating force applied to the pinion gear 166, applied clockwise as shown, to a linear force moving the rack gear 168 in the stacking direction 140. Moreover, the relative length of the actuating lever 218 creates leverage and increases the actuating force as applied in the stacking direction 140 and can thus overcome the insertion or mating resistance associated with the board-to-board electrical connectors 150. To disassemble the first and second board fixtures 160, 162, an opposite actuating force can be applied to the actuating lever 218 of the pinion gear in the opposite direction, counter-clockwise as shown, reversing the meshing of the pinon gear 166 and rack gear 168 and un-mate the electrical connectors 150. Ninety (90°) degrees of angular rotation of the pinion gear 166 may be sufficient to mesh and/or release the rack and pinon gear teeth.

Referring back to FIGS. 2 and 3, to align the pinion gear 166 and the rack gear 168 for meshing, the traverse bracket length 176 of the first and second fixture brackets 170, 172 can be shorter in the traverse direction 144 than the traverse channel length 202 of the fixture channel 190. Accordingly, the first and second channel flanges 194, 196 of the fixture channel 190 extend traversely beyond the traverse edges of the first and second fixture brackets 170, 172 when the first and second board fixtures 160, 162 are assembled. The rack gears 168 fixedly attached to the first and second channel flanges 194, 196 likewise extend traversely beyond the traverse edges of the first and second fixture brackets 170, 172 and are positioned to engage the pinion gears 166 rotatably attached thereon.

To limit or restrict rotation of the pinion gear 166 about the pinion axis 212, referring back to FIG. 7, the pinion gear 166 can include a restraining slot 226 that is disposed into the structural disk 210 and that may extend radially parallel to the pinion periphery 214. The restraining slot 226 is disposed only partly around the pinion axis 212 and forms a geometric arc. The arc-shaped restraint slot 226 can receive a restraint pin 228 that is fixedly mounted on and extends from the exterior face of the first and/or second fixture brackets 170, 172 in the lateral direction 140. Rotation of the pinion gear 166 moves the restraint slot 226 relative to the fixed restraining pin 228, which prevents further rotation when the restraining pin 228 reaches the terminal ends of the restraint slot 226. The geometry of the restraining slot 226 and the location of the restraining pin 228 can be configured to limit angular rotation of the pinon gear 166 to approximately 90 degrees, although other amounts of rotation are possible.

Referring to FIG. 7, rotation of the pinion gear 166 can be associated with a locked position and a released position corresponding to arrangements that secure together or release the first and second board fixtures 160, 162 with respect to the stacking direction 140. To releasably hold the pinion gear 166 with respect to the locked and released positions, the rack-and-pinion mechanism 164a-b can be operatively associated with a ball plunger 230 that is spring-loaded. The ball plunger 230 can be fixedly attached to the circular disk structure 210 of the pinion gear 166. To accommodate the ball plunger 230, the circular disk structure 210 can include a plunger aperture 232 that is radially offset from the pinion axis 212. Accordingly, when the pinion gear 166 is rotated, the ball plunger 230 moves in a radially arc with respect to the pinion axis 212.

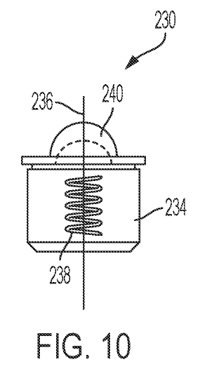

Referring to FIG. 10, the ball plunger 230 can include a hollow tubular cylinder body 234 extending along a plunger axis 236 with a coiled compression spring 238 contained internally therein. One end of the compression spring 238 can be secure to a spherical ball 240 or similar shape which protrudes from an opened axial end of the cylinder body 234. The spherical ball 240 has a diameter or is sized for insertion into the hollow cylinder body 234. The opposite axial end of the cylinder body 234 is blind so insertion of the spherical ball 240 into the cylinder body along the plunger axis axially compresses the compression spring 238. Likewise, the compression spring 238 will displace the spherical ball 240 axially outward from the cylinder body 234.

To interact with the ball plunger, referring to FIG. 7, the first and/or second fixture brackets 170, 172 include a locking detent 242 and a release detent 244 disposed into the exterior faces thereof. The locking and release detents 242, 244 can be dimple shaped hollows having a shape and diameter corresponding to the spherical ball 240. Moreover, the locking and release detents 242, 244 can be radially offset from the pinion axis 212 extending laterally with respect to the fixture brackets 170, 172 and can be angular spaced apart from each other.

When the pinion gear 166 is rotationally attached to the first and/or second fixture brackets 170, 172, the ball plunger 230 can linearly abut the exterior face depressing the spherical ball 240 into the hollow cylinder body 234. However, when the pinion gear 166 rotates to an appropriate position aligning the ball plunger 230 with one of the locking or release detents 242, 244, the spherical ball 240 is axially displaced from the cylinder body 234 by the compression spring 238. The spherical ball 240 is received into one of the locking or release detents 242, 244 and can hold the pinion gear 166 against further rotation. If a sufficient force is applied to the actuating lever 218, however, the biasing force of the compression spring 238 can be overcome depressing the spherical ball 240 again into the cylinder body 234 and allowing rotation of the pinion gear 166 with respect to the pinion axis 212.

Referring to FIG. 2, when the first and second boards 132, 134 are assembled in the board-to-board assembly 130 and the first and second rack-and-pinion mechanisms 164a-b are rotated to the locked position with the actuating levers positioned horizontally to the bottom panel 110, a cover panel can be placed to extend over the board-to-board assembly. The cover panel can be horizontal and parallel to the bottom panel 110 and can be located vertically adjacent to the upper edges of the first and second fixture brackets 170, 172. The cover panel can therefore prevent the first and second rack-and-pinion mechanisms 164a-b from unintentionally rotating and releasing the board-to-board assembly 130.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A board-to-board assembly comprising:
a first board having a planar configuration parallel to a planar orientation associated with the board-to-board assembly;
a first board fixture in a fixed relation to the first board;
a second board having a planar configuration parallel to the planar orientation associated with the board-to-board assembly, the parallel first and second boards spaced apart from each other in a stacking direction orthogonal to the planar orientation;
a second board fixture in a fixed relation to the second board; and
a first rack-and-pinion mechanism and a second rack-and-pinion mechanism each configured for attachment jointly to the first and second board fixtures and concurrently actuatable to translate the first and second boards with respect to the stacking direction.

2. The board-to-board assembly of claim 1, wherein the first rack-and-pinon mechanism and the second rack-and-pinon mechanism are spaced apart in a lateral direction, perpendicular to the stacking direction, toward laterally opposite sides of the board-to-board assembly.

3. The board-to-board assembly of claim 2, wherein the first rack-and-pinon mechanism and the second rack-and-pinon mechanism are spaced apart in a traverse direction, perpendicular to the stacking direction, toward traversely opposite sides of the board-to-board assembly.

4. The board-to-board assembly of claim 1, wherein the first rack-and-pinion mechanism and second rack-and-pinion mechanism each comprise a pinion gear rotationally attached to the first board fixture and a rack gear fixedly attached to the second board gear.

5. The board-to-board assembly of claim 4, wherein the pinion gear comprises a pinion periphery that is circular with a plurality of pinion gear teeth and an actuating lever extending tangentially from the pinion periphery.

6. The board-to-board assembly of claim 5, wherein the pinion gear rotates with respect to a pinion axis that is perpendicular to the stacking direction.

7. The board-to-board assembly of claim 6, wherein the pinion gear comprises a ball plunger that is spring-loaded and adapted to releasably engage a detent disposed on the first board fixture.

8. The board-to-board assembly of claim 7, wherein the pinion gear comprise a restraining slot disposed as an arc and radially parallel to the pinion periphery, the restraining slot receiving a restraining pin extending from the first fixture.

9. The board-to-board assembly of claim 4, wherein the rack gear comprises a linear bar having a plurality of rack gear teeth.

10. The board-to-board assembly of claim 1, wherein the first board fixture comprises a first fixture bracket and a second fixture bracket separated in a lateral direction, perpendicular to the stacking direction, and located toward laterally opposite side of the first board.

11. The board-to-board assembly of claim 10, wherein the first fixture bracket and the second fixture bracket define a lateral bracket gap sized to accommodate a lateral dimension of the first board.

12. The board-to-board assembly of claim 1, wherein the second board fixture is configured as a fixture channel having a channel web parallel with the planar orientation and interconnecting a first channel flange and a second channel flange extending perpendicularly from the channel web, the first and second channel flanges aligned with the stacking direction.

13. The board-to-board assembly of claim 12, further comprising a plurality of board-to-board electrical connectors jointly mounted between the first and second boards.

14. The board-to-board assembly of claim 13, wherein the channel web comprises a plurality of connector apertures to enable mating connection of the plurality of board-to-board electrical connectors.

15. A method of assembling a board-to-board assembly comprising:
situating a first board in a fixed relation to a first board fixture, the first board fixture comprising a pinion gear rotationally attached thereto;
situating a second board in a fixed relation to a second board fixture, the second board fixture comprising a rack gear fixedly attached thereto;
positioning the first board and the second board parallel to each other and separated in a stacking direction;
aligning the pinion gear and the rack gear for engagement;
rotating the pinion gear to mesh with the rack gear and translate the first and second boards towards each other in the stacking direction.

16. The method of claim 15, wherein the pinion gear comprises an actuating lever extending tangentially from a pinion periphery that is circular, and the step of rotating the pinion gear comprises pivoting the actuating lever to generate a mechanical advantage.

17. The method of claim 16, further comprising locking the first and second board fixtures in a stacked relation by engaging a spring-loaded ball plunger mounted to the pinion gear with a locking detent disposed on the first fixture.

18. The method of claim 17, wherein the step of rotating the pinion gear comprises moving a restraining pin extending from the first board fixture within a restraining slot disposed as an arc in the pinion gear.

19. The method of claim 15, wherein the first board fixture comprises a second pinion gear and the second board fixture comprises a second rack gear, and further comprising the step of concurrently rotating the second pinion gear to mesh with the second rack gear.

20. A board-to-board assembly comprising:
a first board having a planar configuration;
a first board fixture in a fixed relation to the first board, the first board fixture comprising a pinion gear rotatably attached thereon;
a second board having a planar configuration parallel to the first board and spaced apart therefrom with respect to a stacking direction orthogonal to first and second boards; and
a second board fixture in a fixed relation to the second board, the second board fixture comprising a rack gear fixedly attached thereto and aligned in the stacking direction, the rack gear adapted to mesh with the pinion gear to move the first and second boards with respect to the stacking direction.
